(19) United States
(12) Patent Application Publication
(10) Pub. No.: US 2016/0134276 A1
(43) Pub. Date: May 12, 2016

(54) SWITCH CIRCUIT FOR VOLTAGE

(71) Applicants: HONG FU JIN PRECISION INDUSTRY (WUHAN) CO., LTD., Wuhan (CN); HON HAI PRECISION INDUSTRY CO., LTD, New Taipei (TW)

(72) Inventors: SONG GUO, Wuhan (CN); CHUN-SHENG CHEN, New Taipei (TW)

(21) Appl. No.: 14/596,598

(22) Filed: Jan. 14, 2015

(30) Foreign Application Priority Data
Nov. 11, 2014 (CN) 201410630126.7

(51) Int. Cl. H03K 17/567; G11C 5/14

(52) U.S. Cl. CPC H03K 17/567; G11C 5/147

(57) ABSTRACT

A switch circuit for voltage includes a power supply module, a platform controller hub (PCH), a basic input-output system (BIOS), and a regulation module. An output pin of the power supply module is coupled to a memory to supply power for the memory. When a type of the memory is changed, an output signal of the PCH is controlled by the BIOS, and the regulation module switches the resistors coupled to a feedback pin of the power supply module, for changing voltage signals output from the power supply module.

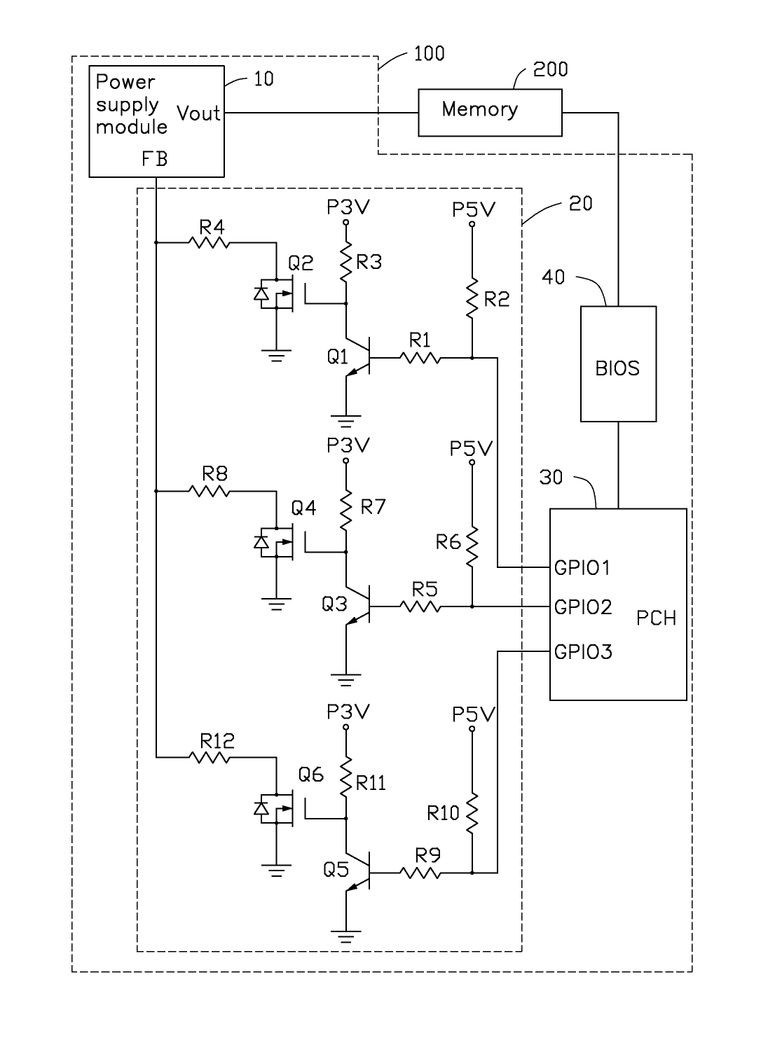

### FIELD

The subject matter herein generally relates to a switch circuit for voltage.

### BACKGROUND

A nominal voltage of a double data rate synchronous dynamic random access memory III (DDR3) of 1.5 volt is different from a nominal voltage of a DDR3 Low Voltage (DDR3L) of 1.35 volt.

### BRIEF DESCRIPTION OF THE DRAWINGS

Implementations of the present technology will now be described, by way of example only, with reference to the attached figure.

The figure is a circuit diagram of an embodiment of a switch circuit for voltage.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

The present disclosure is described in relation to a switch circuit 100 for voltage.

The figure illustrates an embodiment of the switch circuit 100. The switch circuit 100 is coupled to and drives a memory 200. The switch circuit 100 can comprise a power supply module 10, a regulation module 20, a platform controller hub (PCH) 30, and a basic input-output system (BIOS) 40. The memory 200 comprises a serial presence detect (SPD) chip.

An output pin Vout of the power supply module 10 is coupled to the memory 200 for supplying power to the memory 200. In at least one embodiment, the BIOS 40 is coupled between the PCH 30 and the memory 200. The PCH 30 is coupled to a feedback pin FB of the power supply module 10 through the regulation module 20.

The regulation module 20 can comprise first to sixth electronic switches Q1-Q6 and first to twelfth resistors R1-R12. A control terminal of the first electronic switch Q1 is coupled to a first input output pin GPIO1 of the PCH 30 through the first resistor R1. The first input output pin GPIO1 of the PCH 30 is coupled to a first power supply P5V through the second resistor R2. A first terminal of the first electronic switch Q1 is coupled to a second power supply P3V through the third resistor R3. A second terminal of the first electronic switch Q1 is coupled to ground. A control terminal of the second electronic switch Q2 is coupled to the first terminal of the first electronic switch Q1. A first terminal of the second electronic switch Q2 is coupled to the feedback pin FB of the power supply module 10 through the fourth resistor R4. A second terminal of the second electronic switch Q2 is coupled to ground.

A control terminal of the third electronic switch Q3 is coupled a second input output pin GPIO2 of the PCH 30 through the fifth resistor R5. The second input output pin GPIO2 of the PCH 30 is coupled to the first power supply P5V through the sixth resistor R6. A first terminal of the third electronic switch Q3 is coupled to the second power supply P3V through the seventh resistor R7. A second terminal of the third electronic switch Q3 is coupled to ground. A control terminal of the fourth electronic switch Q4 is coupled to the first terminal of the third electronic switch Q3. A first terminal of the fourth electronic switch Q4 is coupled to the feedback pin FB of the power supply module 10 through the eighth resistor R8. A second terminal of the fourth electronic switch Q4 is coupled to ground.

A control terminal of the fifth electronic switch Q5 is coupled a third input output pin GPIO3 of the PCH 30 through the ninth resistor R9. The third input output pin GPIO3 of the PCH 30 is coupled to the first power supply P5V through the tenth resistor R10. A first terminal of the fifth electronic switch Q5 is coupled to the second power supply P3V through the eleventh resistor R11. A second terminal of the fifth electronic switch Q5 is coupled to ground. A control terminal of the sixth electronic switch Q6 is coupled to the first terminal of the fifth electronic switch Q5. A first terminal of the sixth electronic switch Q6 is coupled to the feedback pin FB of the power supply module 10 through the twelfth resistor R12. A second terminal of the sixth electronic switch Q6 is coupled to ground.

The first to third input output pins GPIO1-GPIO3 of the PCH 30 output high level signals when the memory 200 is confirmed to be a DDR3 by the BIOS 40. The first electronic switch Q1, the third electronic switch Q3, and the fifth electronic switch Q5 are turned on. The second electronic switch Q2, the fourth electronic switch Q4, and the sixth electronic switch Q6 are turned off. A resistance between the feedback pin FB of the power supply module 10 and ground is zero. A 1.5 volt voltage signal is output to the memory 200 from the output pin Vout of the power supply module 10.

The first input output pin GPIO1 of the PCH 30 outputs a low level signal and the second input output pin GPIO2 and the third input output pin GPIO3 of the PCH 30 output high level signals when the memory 200 is confirmed to be a DDR3L by the BIOS 40. The first electronic switch Q1 is turned off and the second electronic switch Q2 is turned on. The third electronic switch Q3 and the fifth electronic switch Q5 are turned on. The fourth electronic switch Q4 and the sixth electronic switch Q6 are turned off. The feedback pin FB of the power supply module 10 is coupled to ground through the fourth resistor R4. The resistance between the feedback pin of the power supply module 10 and ground is the resistance of the fourth resistor R4. A 1.35 volt voltage signal is output to the memory 200 from the output pin Vout of the power supply module 10.

Different voltage signals are output from the output pin Vout of the power supply module 10 according to the resistance between the feedback pin FB of the power supply module 10 and ground, that is, the feedback pin FB is grounded through different resistors. In at least one embodiment, the feedback pin FB of the power supply module 10 can be coupled to ground through one or two or three of the fourth resistor R4, the eighth resistor R8, and twelfth resistor R12.

In at least one embodiment, the BIOS 40 controls output signals of the PCH 30 according to the types of the memory 200.

In other embodiments, the BIOS 40 do not connect to the memory 200 and output signals of the PCH 30 are directly controlled according to a selection menu of the BIOS 40.

In at least one embodiment, the first electronic switch Q1, the third electronic switch Q3, and the fifth electronic switch Q5 can be npn bipolar junction transistors, and the second electronic switch Q2, the fourth electronic switch Q4, and the sixth electronic switch Q6 can be n-channel field effect transistors.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A switch circuit for voltage comprising:
a power supply module, wherein an output pin of the power supply module is coupled to the memory for supplying power to a memory;
a platform controller hub (PCH);
a basic input-output system (BIOS) coupled to the PCH for controlling output signals of the PCH according to types of the memory; and
a regulation module comprising a first electronic switch, a second electronic switch, a first resistor, a second resistor, a third resistor, and a fourth resistor, wherein a control terminal of the first electronic switch is coupled to a first input output pin of the PCH through the first resistor, the first input output pin of the PCH is coupled to a first power supply through the second resistor, a first terminal of the first electronic switch is coupled to a second power supply through the third resistor, a second terminal of the first electronic switch is coupled to ground, a control terminal of the second electronic switch is coupled to the first terminal of the first electronic switch, a first terminal of the second electronic switch is coupled to a feedback pin of the power supply module through the fourth resistor, and a second terminal of the second electronic switch is coupled to ground;
wherein the first terminal of the first electronic switch is connected to the second terminal of the first electronic switch in response to the control terminal of the first electronic switch receiving a high level signal, and the first terminal of the first electronic switch is disconnected from the second terminal of the first electronic switch in response to the control terminal of the first electronic switch receiving a low level signal;
wherein the first terminal of the second electronic switch is connected to the second terminal of the second electronic switch in response to the control terminal of the second electronic switch receiving a high level signal, and the first terminal of the second electronic switch is disconnected from the second terminal of the second electronic switch in response to the control terminal of the second electronic switch receiving a low level signal.

2. The switch circuit of claim 1, wherein the regulation module further comprises third to sixth electronic switches and fifth to twelfth resistor, a control terminal of the third electronic switch is coupled a second input output pin of the PCH through the fifth resistor, the second input output pin of the PCH is coupled to the first power supply through the sixth resistor, a first terminal of the third electronic switch is coupled to the second power supply through the seventh resistor, a second terminal of the third electronic switch is coupled to ground, a control terminal of the fourth electronic switch is coupled to the first terminal of the third electronic switch, a first terminal of the fourth electronic switch is coupled to the feedback pin of the power supply module through the eighth resistor, a second terminal of the fourth electronic switch is coupled to ground, a control terminal of the fifth electronic switch is coupled a third input output pin of the PCH through the ninth resistor, the third input output pin of the PCH is coupled to the first power supply through the tenth resistor, a first terminal of the fifth electronic switch is coupled to the second power supply through the eleventh resistor, a second terminal of the fifth electronic switch is coupled to ground, a control terminal of the sixth electronic switch is coupled to the first terminal of the fifth electronic switch, a first terminal of the sixth electronic switch is coupled to the feedback pin of the power supply module through the twelfth resistor, and a second terminal of the sixth electronic switch is coupled to ground.

3. The switch circuit of claim 1, wherein the output of the PCH accord to the types of the memory from a serial presence detect chip of the memory.

4. The switch circuit of claim 1, wherein the output of the PCH accord to a selection menu of the BIOS.

5. The switch circuit of claim 1, wherein the first electronic switch is an NPN bipolar junction transistor.

6. The switch circuit of claim 1, wherein the second electronic switch is an n-channel field effect transistor.

7. The switch circuit of claim 2, wherein the third electronic switch and the fifth electronic switch are NPN bipolar junction transistor.

8. The switch circuit of claim 2, wherein the fourth electronic switch and the sixth electronic switch are n-channel field effect transistor.

9. A switch circuit for voltage comprising:
a power supply module for supplying power to a memory according to a resistance between a feedback pin of the power supply module and ground;
a PCH comprising a plurality of input output pins;
a BIOS coupled to the PCH for controlling output signals of the PCH according to types of the memory; and
a regulation module comprising a plurality of resistors respectively corresponding to the input output pins of the PCH, the output signals of input output pins of the PCH respectively configured to control whether the corresponding the feedback pin is grounded through the corresponding resistor.

10. The switch circuit of claim 9, wherein a first electronic switch and a second electronic switch are coupled between each of the resistor and the corresponding input output pin, a control terminal of the first electronic switch is coupled the corresponding input output pin, a first terminal of the first electronic switch is coupled to a power supply, a second terminal of the first electronic switch is grounded, a control terminal of the second electronic switch is coupled the first terminal of the first electronic switch, a first terminal of the second electronic switch is coupled to the resistor, a second terminal of the second electronic switch is grounded, when the first electronic switch is turned on, the second electronic switch is turned off; when the first electronic switch is turned off, the second electronic switch is turned on.

11. The switch circuit of claim 10, wherein the resistors are with different resistances.

12. The switch circuit of claim 9, wherein the memory is coupled between the PCH and the BIOS.
